(19) United States
(12) Patent Application Publication
(10) Pub. No.: US 2012/0074971 A1
(43) Pub. Date: Mar. 29, 2012

(54) MEASURING DEVICE FOR ELECTRICALLY MEASURING A FLAT MEASUREMENT STRUCTURE THAT CAN BE CONTACTED ON ONE SIDE

(75) Inventors: Markus Glatthaar, Freiburg (DE); Stefan Rein, Denzlingen (DE); Daniel Biro, Freiburg (DE); Florian Clement, Freiburg (DE); Michael Menko, Grafenau (DE); Alexander Krieg, Freiburg (DE)

(73) Assignee: FRAUNHOFER-GESELLSCHAFT ZUR FORDERUNG DER ANGEWANDTEN FORSCHUNG E.V., Munchen (DE)

(21) Appl. No.: 13/255,557

(22) PCT Filed: Mar. 10, 2010
(86) PCT No.: PCT/EP2010/001493

§ 371 Date: Nov. 17, 2011

(30) Foreign Application Priority Data
Mar. 10, 2009 (DE) 10 2009 012 021.1

(51) Int. Cl. G01R 31/00

(52) U.S. Cl. 324/750.2

(57) ABSTRACT

A measuring device for electrically measuring a measurement structure that can be electrically contacted at one measuring side, in particular an optoelectronic element, such as a solar cell, including at least two contacting units for electrically contacting the measurement structure and at least one support element for supporting the measurement structure with the measuring side on the support element. It is essential that the measuring device includes at least one suction line for the connection to the suction unit and at least one suction opening that is connected in a fluid-conducting manner to the suction line, wherein the suction opening is arranged in and/or on the support element such that the measurement structure can be pressed against the support element by suctioning via the suction opening. When the measurement structure rests on the support element, the contacting unit can be pressed against the measuring side of the measurement structure for the electrical contacting thereof.

### BACKGROUND

The invention relates to a measuring device as well as a method for electrically measuring a measurement structure that can be electrically contacted on one side, particularly an opto-electronical elements, such as a solar cell.

In opto-electronical elements and particularly solar cells structures are known, in which all contacts for an electrical contact are arranged on one measuring side of the measurement structure. For test purposes, calibration, or measuring it is therefore necessary in a measuring design to electrically contact the measurement structure on one side at the contacting points provided. In particular, in measurement structures, which are embodied to emit or transform electromagnetic radiation at the side opposite the measuring side, the problem arises that on the one hand, contacting must occur at the measuring side and on the other hand the side opposite said measuring side should be influenced only to a minor extent with regards to the permeability for electromagnetic radiation during the measuring or calibration process, because during the measurement and/or calibration an impingement of the measurement structure occurs with electromagnetic radiation and/or the electromagnetic radiation emitted during the measurement process is to be measured. This is particularly the case during the measurement of solar cells and large-surface LED and/or OLED-elements that can be contacted at one side.

Measurement devices are already known for solar cells that can be contacted at one side, in which a solar cell with a measuring side is placed upon a support element of the measuring device and is pressed to said support element via a glass pane. At the side of the support element, contacting pins are pressed to the contacting points of the solar cell so that an electric contacting occurs.

In this measuring device it is disadvantageous that on the one hand the placement of the solar cell onto the support element and the subsequent compression via a glass pane represents an expensive process, which is particularly time-consuming in case of measuring a multitude of solar cells in a production line. On the other hand, the glass panes used exhibit absorption and reflection features, which falsify the measurement results and/or must be considered by appropriate calibration for said measurement results. Furthermore, the glass pane may be soiled or damaged during operation so that additional corruptions may occur during the measurement process.

### SUMMARY

The present invention is therefore based on the objective to provide a measuring device and a method for measuring a measurement structure that can be electrically contacted at one measuring side, in which during the measurement process the side of the measurement structure opposite the measuring side has a lower interference with regards to electromagnetic radiation impinging the measurement structure or being emitted by the measurement structure and the side opposite the measuring side is exposed to lower mechanical stress. Furthermore, the electric contacting of the measurement structure should be possible within a shorter period of time than in measurement devices of prior art and the measuring device is improved with regards to its susceptibility due to soiling or damages.

This objective is attained in a measuring device as well as a method according to the invention.

The measuring device according to the invention for electrically measuring a measurement structure that can be electrically contacted at one measuring side, particularly an opto-electronic element, such as a solar cell, therefore comprises at least two contacting units for electrically contacting the measurement structure and at least one support element for placing the measurement structure with the measuring side onto the support element. The support element and the contacting element are arranged such that the measurement structure resting on the support element can be contacted in an electrically conductive fashion via the contacting units at the measuring side. Furthermore, the two contacting units are electrically isolated from each other because typically electrically opposite poles of the measurement structure contact the two contacting units.

The measuring device according to the invention comprises at least one suction line for connecting to a suction unit and at least one suction opening, connected to the suction line in a fluid-conducting, at least gas-conducting fashion. The suction opening is arranged in and/or at the support element such that the measurement structure can be pressed via the suction opening to the support element by way of suction.

Furthermore, the contacting units are arranged articulated in reference to the support element such that for a measurement structure resting on the support element the contacting units can be pressed to the measuring side of the measurement structure for electrically contacting. In order to press the contacting units, the measuring device comprises an active actuator unit, which is in an effective contact with the contacting units such that via said actuator unit the contacting units can optionally be pressed to the measurement structure resting on the support element for contacting it.

Here, the measuring device is embodied such that when the contacting units are pressed to the measurement structure, the measurement structure is exclusively pressed to the support element by way of suction and perhaps the weight of the measurement structure.

Contrary to prior art, here no mechanical pressing of the measurement structure to the support structure occurs by a glass plate or any similar means. Rather, in the measuring device according to the invention the measurement structure is exclusively pressed to the support element by way of suctioning using at least one suction opening. Typically, measuring occurs with a horizontally positioned measurement structure, with the measuring side pointing downwards, so that the weight of the measurement structure also contributes slightly to a compression force towards the support element. Due to the fact that typical measurement structures, particularly solar cells, have only a low weight, the weight force is typically negligible compared to the suctioning, on the one hand, and the compression forces arising by the contacting units to the measurement structure, on the other hand.

An essential difference of the measuring device according to the invention in reference to measurement devices of prior art therefore comprises that the forces enacted by the contacting units upon the measurement structure are exclusively compensated by the suctioning of the measurement structure and perhaps its weight, while in measurement devices of prior art mechanical means are required, such as the above-mentioned glass pane.

This results in the measuring devices according to the invention having several advantages:

The compression of the measurement structure to the support element occurs only by switching the suction on or off, using the suction opening. Thus, it is not necessary to arrange mechanical means, such as a glass pane, over the measurement structure so that a considerably faster contacting is possible compared to measuring devices of prior art. Furthermore, no elements of the measuring device are located on the side of the measurement structure opposite the measuring side so that electromagnetic radiation can enter into and be emitted from the measurement structure without being hindered. Thus, particularly no correction or calibration of a measurement is required due to any potential reflection or absorption of electromagnetic radiation by elements of said measurement structure. Additionally, in the method according to the invention no mechanical stress occurs at the side of the measurement structure opposite the measuring side, such as by compression elements known from prior art. This way it is excluded that any damages at the side opposite the measuring side occurs by such compression elements.

Preferably the measuring device comprises a control unit, which controls both the actuator unit as well as the above-mentioned vacuum control unit so that upon switching on the vacuum and thus the start of the suction process of the measurement structure to the support element the contacting units are pressed via the actuator unit to the measurement structure, however the temporal progression of the compression of the contacting units occurs adjusted such that the measurement structure is not lifted off the support element. Preferably after the start of the suctioning process the contacting units are compressed with a time-delay via the actuator to the measuring structure so that first sufficient vacuum is formed for pressing the measurement structure to the support element and subsequently the compression of the contacting units to the measurement structure occurs.

Preferably the measurement structure comprises a vacuum control unit, which is interposed between the suction unit and the suction line for alternating switching of the suction on and off.

Therefore, upon placing the measurement structure onto the support element, suctioning occurs via the suction line and the suction opening, i.e. a vacuum is created by the suction line in reference to the ambient pressure which leads to a compression force of the measurement structure upon the support element in the area of the suction opening. Due to the fact that the vacuum is not created instantaneously the compression force of the measurement structure onto the support element is not instantaneously present, either. Thus, an essential element of the measuring device is the active actuator unit, by which the contacting unit can optionally be compressed to the measurement structure resting on the support element. Thus, via the actuator unit it can be controlled at which point of time and by which temporal progression the contacting units are pressed against the measuring side of the measurement structure with the force desired for electric contacting.

Advantageously, the suction opening and the actuator unit are therefore embodied such that during the suctioning of the measurement structure to the support element and the compression of the contacting pins to the measurement structure for their electric contacting the total of the suction forces by which the measurement structure is pressed to the support element is always greater than the total of all contacting forces by which the contacting units are pressed to the measuring side of the measurement structure. This way it is therefore excluded that the measurement structure is lifted off the support element by the pressure of contacting forces to the measurement structure.

In particular it is possible to embody the actuator unit such that during the suctioning the approach of the contacting units to the measurement structure and respectively the compression process of the contacting unit to the measuring side of the measurement structure occurs such that the total of the suction forces by which the measurement structure is pressed to the support element is always greater than the total of the contacting forces by which the contacting units are pressed to the measuring side of the measurement structure. This particularly avoids that during the compression process of the contacting units to the measurement structure said measurement structure lifts off the support element.

The actuator unit is preferably embodied such that the contacting units are displaceable via the actuator unit optionally into a resting position, in which no electric contacting occurs with the measurement structure resting on the support structure, and a contacting position, in which the measurement structure resting on the support element is electrically contacted by the contacting units.

This way, before and after the measurement process a displacement of the contacting units can occur into the resting position, so that upon placement and removal of the measurement structure any scratching thereof by the contacting units is avoided. Furthermore, an adjustment of the measurement structure is possible, preferably via stops applied to the measuring device, without any distance of the measurement structure from the support element being given by the contacting units, which might lead to an instable position of the measurement structure.

Advantageously, the measuring device comprises a control unit, by which the complete displacement of the contacting units into the contacting position can be detected. A technically particularly simple realization results by electric sensors, known per se, which are arranged such that their circuits are only closed in case of a completed displacement of the contacting elements into the contacting position. This way, the user can easily control if the contacting position has been reached, for example by a control light. Additionally or alternatively the sensor or sensors is/are connected to an inlet of the control unit such that the control of the measurement process, particularly the rising of the contacting unit into the contacting position and the start of the measurement process, can be controlled dependent on the status of the sensors such that the measurement process is only initiated by the control unit upon a completed displacement of the contacting elements into the contacting position.

In another preferred embodiment the measuring device comprises at least two suction openings, with one suction opening being respectively arranged in the area of the contacting units for each of the two contacting units. In particular, it is advantageous for the contacting unit to be arranged at a distance of less than 1 cm, furthermore particularly less than 5 mm from the corresponding contacting unit. This ensures that lateral stress in the measurement structure between the suction opening and the contacting unit due to oppositely acting forces at the suction opening and the contacting unit influences only small area of the measurement structure and thus the risk for destroying the measurement structure by potentially occurring shearing forces is reduced.

Furthermore, it is advantageous for the support element to comprise at least one recess and the contacting elements to be guided by one or more recesses of the support element when an electric contact occurs. Furthermore, in this preferred embodiment at least one recess is embodied as a suction opening, through which at least one contacting unit is guided during the contact. This way, a minimal distance is ensured by the contacting units between the suction force and the compression force to the measurement structure because within the suction opening simultaneously the measurement structure is impinged with a compression by the compression of the contacting unit. This way, the risk of damaging the measurement structure is further reduced. Furthermore this embodiment allows a cost-effective and simple production of the measuring device because only one recess is required for both the suctioning as well as the guiding of the contacting unit.

In particular it is advantageous to guide several contacting units through one suction opening. Preferably the measuring device is embodied such that upon contacting the measurement structure several contacting units are guided through the recess embodied as a suction opening, particularly preferred two, three, or four contacting units. This way the separate measurement of voltage and current is possible using methods of four-wire measurement technology known per se.

Furthermore, it is advantageous to guide at least one contacting unit each through two locally separated suction openings of the support element and to connect the suction openings via a channel in the support element in a fluid-guiding fashion. This way, any creation of a vacuum at the suction opening also creates a vacuum at the other suction opening connected in a fluid-guiding fashion. Preferably the fluid-guiding channel is embodied open in the direction of the measurement structure or at least partially open so that upon the creation of a vacuum the measurement structure is not only pressed to the suction openings themselves but also to the support element at the area of the fluid-guiding channel open in the direction of the measurement structure so that the area at which the measurement structure is suctioned to the support element is enlarged and thus a lower mechanical stress impinges upon the measurement structure.

Typically the support element is embodied as a cooling element, which preferably is connected to a cooling unit and particularly preferred comprises cooling cycles through which a coolant flows.

This way, a temperature can be adjusted according to predetermined measurement conditions for the measurement structure by an appropriate climate-control of the support element. In this case it is desirable to create a thermal contact surface between the measurement structure and the support element as large as possible so that another advantage develops during the guiding of the contacting units through the suction opening due to the enlarged contact surface.

The active actuator unit preferably comprises actuator for displacing the contacting units, by which the contacting units can be pressed to the measuring side of the measurement structure resting on the support element. The actuator may comprise, for example, electric motors for displacing the contacting units.

In an advantageous embodiment the actuator unit comprises at least one vacuum chamber, which on the one side is connected to the suction line and at the other side with at least one suction opening in a fluid-guiding fashion. The vacuum chamber is embodied compressible with respect to its volume by creating a vacuum in the vacuum chamber. Furthermore, at least one contacting unit and preferably all contacting units are arranged in the vacuum chamber such that upon compressing the vacuum chamber the contacting unit is pressed at the measuring side to the measurement structure resting on the support element. In this advantageous embodiment the displacement of the contacting units therefore occurs by the vacuum created by the suction line connected to the suction unit. The vacuum in turn leads on the one side to a suctioning of the measurement structure to the support element; simultaneously a compression occurs of the volume of the vacuum chamber, which in turn causes the contacting units to be pressed to the measuring side of the measurement structure. In this advantageous embodiment therefore no additional motors or other active means for motion are necessary, thus the active movement of the contacting units occurs via the suction unit by compressing the vacuum chamber. This way, particularly a temporal synchronization of the suctioning of the measurement structure to the support element on the one side and the compression of the contacting units to the measuring side of the measurement structure on the other side is yielded in a simple fashion.

Preferably, the vacuum chamber comprises a floor aligned approximately parallel in reference to the support element, on which the contacting units are mounted and the vacuum chamber is embodied such that upon compression of the vacuum chamber its floor moves in the direction of the support element, with the floor always remaining essentially parallel in reference to the support element. This is preferably ensured by respective guide rails between the support element and the floor of the vacuum chamber.

In a preferred embodiment, the actuator unit comprises at least two vacuum chambers. Each vacuum chamber comprises at least one mobile fastening element for the contacting unit, preferably a mobile piston, which is supported in the vacuum chamber in a protractible and retractable fashion. At least one contacting unit is arranged on or at each fastening element so that upon the insertion of the fastening element into the vacuum chamber the contacting unit is pressed against the measuring side of the measurement structure resting on the support element. The scope of the invention also includes that the fastening element represents an element of the contacting unit, for example its housing.

Each vacuum chamber is connected via the suction line or via a separate suction line each to the suction unit. In this advantageous embodiment a vacuum, created in the vacuum chamber, results both in a compression of the vacuum chamber such that the mobile fastening element moves into the vacuum chamber so that the volume of the vacuum chamber reduces. This advantageous embodiment has the advantage that by selecting the ratio between the cross-sectional surface of the mobile fastening element and the area of the vacuum chamber perpendicular in reference to the direction of motion of the fastening element the ratio of force can be selected between the suction force to suction the measurement structure to the support element and the compression force by which the contacting unit or the contacting units are pressed to the measurement structure. Therefore, for a predetermined force ratio a respective dimensioning between the opening area of the vacuum chamber towards the sample and the cross-sectional area of the fastening element can be selected in a simple fashion, which leads to the predetermined force ratio when creating the vacuum. This way, expensive controls, such as required for synchronizing the creation of the vacuum and the displacement of the contact pin via an electric motor are not necessary.

Preferably, the plunger is arranged in the vacuum chamber such that it essentially projects into the vacuum chamber and retracts therefrom perpendicularly in reference to the support element. It is particularly advantageous when in the two above-mentioned preferred exemplary embodiments the contacting units each are pressed to the measurement structure via the suction opening of the vacuum chamber.

Preferably, in the above-mentioned preferred embodiment the support element is embodied with sufficient thickness so that the vacuum chambers are embodied as recesses in said support element and the fastening elements are arranged respectively mobile at the support element such that the fastening elements can be protracted into the vacuum chamber embodied in the support element and/or retracted therefrom.

The suction opening is advantageously embodied and arranged such that when the measurement structure rests on the support element the suction opening essentially contacts the measurement structure in a fluid-tight fashion.

The contacting units are preferably embodied as spring-loaded contacts known per se. Such spring-loaded contacts typically comprise a cylindrical plunger, which is spring-loaded and allocated to a cylindrical housing such that upon impingement with force the contacting plunger can be inserted into the cylindrical housing, with the spring force counteracting said insertion.

These spring-loaded contact pins are commercially available in multiple embodiments with regards to the form of the contacting head (for example round or provided with tips) and the spring force so that the compression forces advantageous for the given measurement situation can be realized upon contacting by the respective selection of commercial spring-loaded contact pins.

Here, it is advantageous for the actuator unit to comprise at least one stop, which limits the maximum displacement path of the contacting unit in the direction of the measurement structure. This way, the maximum displacement of the contacting units up to the above-mentioned stop represents a predetermined stroke, by which the plunger of the spring-loaded contact pins is pressed into the cylindrical housing. Accordingly, by the arrangement of the stop the compression force can be preselected by which the plunger of the spring-loaded contact pins is pressed against the measuring side of the measurement structure. This way, particularly consistent measurement conditions can be realized in consecutive measurements by equal compression forces of the contacting units upon the measurement structure.

As already mentioned, the vacuum during the suction of the measurement structure does not develop instantaneously but a gradual increase of the compression force of the measurement structure to the support element occurs via the suction. In a preferred embodiment the actuator unit therefore comprises at least one delay element, which is embodied cooperating with the contacting units such that upon the displacement of the contacting units via the actuator unit the speed of displacement of the contacting units is reduced by the delay element. This prevents that during the development of the vacuum and the corresponding creation of the suction force the total of the compression force of the contacting units to the measurement structure is greater than the vacuum developing. Accordingly the delay element prevents the measurement structure from lifting off the support element.

Advantageously the delay unit is embodied as a dampening element, particularly a hydraulic dampening element, which is embodied cooperating with the actuator unit such that the displacement of the contacting units for pressing it to the measuring side of the measurement structure is delayed.

Additionally, the scope of the invention also covers to embody the delay element as a pneumatic cylinder, which is preferably controlled via a pressure valve so that the predetermined delaying effect occurs. In another embodiment the delay element is embodied as a pre-stressed coil spring, which counteracts the displacement of the contacting units for contacting the measuring side of the measurement structure via a spring force.

In the above-described preferred embodiments of the measuring device comprising a vacuum chamber it is particularly advantageous for the delay element to be embodied as a delay vacuum chamber. This delay vacuum chamber is arranged together with the first vacuum chamber such that any compression of the first vacuum chamber is delayed by a vacuum in the second vacuum chamber. The delay vacuum chamber therefore creates a force counteracting the compression of the first vacuum chamber so that the compression is delayed and accordingly the approach of the contacting units to the measurement structure is also delayed. Advantageously the measuring device comprises a second suction line, which is connected to the delay vacuum chamber in a fluid-guiding fashion, so that via the second suction line a vacuum can be predetermined in the delay vacuum chamber using a suction unit.

Here, it is particularly advantageous if an adjustable pressure valve is arranged between the first and the second vacuum chamber, which releases a gas flow from the delay vacuum chamber upon reaching a preset pressure difference, however blocking the opposite direction. By setting the pressure difference in advance, at which the gas begins to flow from the delay vacuum chamber into the first vacuum chamber the delayed effect of the delay vacuum chamber can be predetermined. The greater the predetermined pressure difference the greater the delayed effect. Examinations of the applicant have shown that for typical applications at rear-contacted solar cells in industrial production preferably a pressure difference ranging from 0.02 to 0.3 bar, preferably ranging from 0.05 to 0.1 bar, particularly at 0.1 bar is predetermined in order to cause sufficient delay for spring-loaded contact pins typically used for such applications.

In the above-described preferred embodiment of the measuring device comprising a vacuum chamber and the delay element embodied as a delay vacuum chamber a measurement occurs preferably such that first the measurement structure is placed upon the measuring device, with the contacting units being positioned in a resting state and the vacuum chamber having ambient pressure conditions. Upon placement of the measurement structure the pressure in the vacuum chamber is reduced in reference to the ambient pressure, however, here the pressure in the delay vacuum chamber is always lower than the pressure in the vacuum chamber so that on the one side by compressing the vacuum chamber the contacting units are inserted moved into the contacting position, however this movement is delayed by the fact that in the delay vacuum chamber a lower pressure exists in reference to the vacuum chamber. The pressure in the vacuum chamber is further reduced until it is equal or preferably lower than the pressure in the delay vacuum chamber and the contacting units are completely moved into the contacting position. The measurement structure is now contacted and the measurement occurs. Subsequently the pressure of the vacuum chamber is readjusted to the environmental pressure, i.e. a “venting” of the vacuum chamber occurs so that the measurement structure is no longer suctioned to the measuring device and the contacting elements are displaced into their resting position. Here, preferably the pressure in the delay vacuum chamber is always lower than the ambient pressure so that the displacement of the contacting elements from the contacting position into the resting position is accelerated by the pressure in the delay-vacuum chamber being lower in reference to the ambient pressure, during this step the delay vacuum chamber quasi suctions the contacting elements into the resting position so that a more rapid displacement of the contacting elements into the resting position occurs compared to the same processing step if the delay vacuum chamber would show ambient pressure.

In another preferred embodiment the measuring device comprises the above-described vacuum chamber and a second vacuum chamber, which is embodied identical to the delay vacuum chamber, however being used differently: In this preferred embodiment, as described above, first the measurement structure is placed upon the measuring device and subsequently by reducing the pressure in the vacuum chamber a displacement of the contacting elements occurs into the contacting position, with contrary to the previously described process in this case the second vacuum chamber always shows ambient pressure so that no delay of the displacement of the contacting elements into the contacting position occurs by the second vacuum chamber. After a complete displacement of the contacting elements into the contacting position the measurement structure is contacted and the measurement occurs. Subsequently a displacement of the contacting elements occurs into the resting position such that the vacuum chamber is “vented”, i.e. the pressure of the vacuum chamber is adjusted to the ambient pressure, with simultaneously the pressure in the second vacuum chamber being reduced so that, as described above, a “suctioning” occurs of the contacting elements into the resting position due to the lower pressure in the second vacuum chamber and thus the motion of the contacting elements from the contacting position into the resting position is accelerated due to the reduced pressure in the second vacuum chamber. In this case, an acceleration of the displacement occurs from the contacting position into the resting position by a vacuum in the second vacuum chamber, however no delay of the displacement of the contacting element from the resting position into the contacting position.

The two above-described chambers are embodied cooperating such that any reduction of the volume of one chamber results in an increase of the volume of the other chamber and vice versa. This occurs independent from the second chamber being embodied to delay the displacement from the resting position into the contacting position, to accelerate the displacement from the contacting position into the resting position, or both of them.

In another advantageous embodiment of the measuring device according to the invention the support element is embodied interchangeably and the measuring device comprises several support elements for different contacting points of a measurement structure, with each support element comprising recesses according to the respectively predetermined contacting points. This way, the measuring device can easily be adjusted to different measurement structures with differently arranged contacting points by exchanging the support elements. Advantageously the contacting units can be arranged at different places of the actuator unit so that the contacting units can be arranged appropriately for different measurement structures by displacing the respective contacting points.

In another advantageous embodiment the actuator unit is also interchangeable and the measuring device comprises several actuator units, with the actuator units being embodied according to the support elements with different measurement structures according to the respective arrangement of the contacting points.

Furthermore it is advantageous for the support element of the measuring device according to the invention to be embodied interchangeably and for the measuring device to comprise several support elements with suction openings for different suction forces with the support elements being different with regards to the overall size of the suction openings.

The invention further comprises a method for contacting a measurement structure that can be electrically contacted at one measuring side, particularly an opto-electronic element, such as a solar cell, with the method preferably being performed with a measurement structure according to the invention and/or an above-mentioned advantageous embodiment.

The method according to the invention comprises the following processing steps:
A. Placing the measurement structure with a measuring side onto a support element, and
B. electrically contacting the measurement structure, by at least two contacting units, electrically isolated from each other, being pressed to the measuring side of the measurement structure.

It is essential that the measurement structure in step B is suctioned via a vacuum to the support element via suction openings at and/or in the support element for contacting and that upon contacting the measurement structure they are pressed to the support element exclusively via suction and perhaps the weight of the measurement structure.

This way, as described above, influence on the electromagnetic radiation received or emitted at the side opposite the measuring side of the measurement structure by additional elements, such as a glass pane, is avoided. Furthermore, a more rapid change of the measurement structures and accordingly a more rapid sequence of measurements is possible using different measurement structures.

Preferably, during the compression process of the contacting units to the measuring side of the measurement structure and during a measuring process with contacting units pressed to the measurement structure the suction force, by which the measurement structure is pressed to the support element, is always greater than the total of contacting forces by which the contacting units are pressed to the measuring side of the measuring structure. This way, the measurement structures is prevented from lifting off the support element.

In another advantageous embodiment of the method according to the invention a delayed approach of the contacting units to the measuring side of the measurement structure occurs in step B. This way the measurement structure is prevented from lifting off the support element when the contacting units approach, because due to the delay sufficient time is given to create a respective vacuum and thus sufficient suction power of the measurement structure remains at the support element.

Preferably the method according to the invention is performed via a measuring device having at least one vacuum chamber, which can be compressed as described above with regards to its volume by creating a vacuum and at least one contacting unit being arranged in or at said vacuum chamber with the compression of the contacting unit to the measurement structure occurring such that a vacuum is created in the vacuum chamber.

### BRIEF DESCRIPTION OF THE DRAWINGS

In the following, additional features and advantageous embodiments of the invention are explained in greater detail using the exemplary embodiments and the figures. Here, shown are:

FIG. 1 an exemplary embodiment of the measuring device according to the invention with two vacuum chambers, with the second vacuum chamber being a delay vacuum chamber,

FIG. 2 an exemplary embodiment of a measuring device according to the invention with two vacuum chambers, with each vacuum chamber comprising a fastening element, embodied as a mobile piston, which is supported such that it can protract into the vacuum chamber and be retracted therefrom,

FIG. 3 another exemplary embodiment according to a measuring device according to the invention in a top view, with several vacuum chambers being connected in a fluid-conducting fashion via channels formed in a support element,

FIG. 4 a cross-section through a line marked A in FIG. 3 and perpendicularly to the drawing plane of FIG. 3, with the illustration in FIG. 4 not being proportional in reference to FIG. 3.

### DETAILED DESCRIPTION OF THE PREFERRED EMBODIMENTS

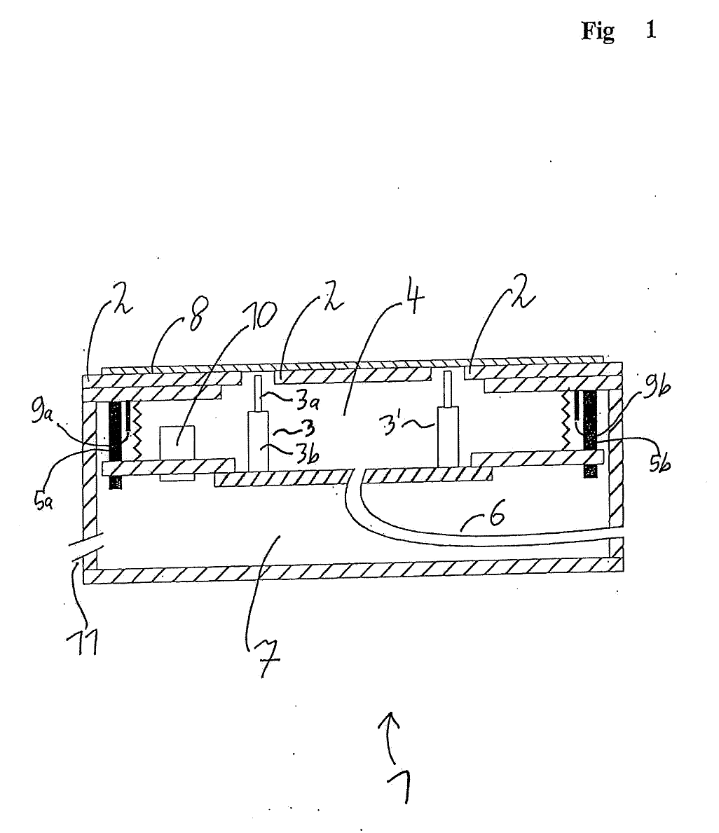

FIG. 1 shows schematically a cross-section through an exemplary embodiment of a measuring device 1 according to the invention, with the cross-section extending perpendicularly in reference to a support element 2. The support element 2 is embodied in one piece and comprises two recesses, through which the cross-section extends shown in FIG. 1.

The measuring device comprises a multitude of contacting units 3, with two (3, 3′) of them being shown in the cross-section depicted in FIG. 1. The contacting units 3 are embodied as spring-loaded contact pins, comprising a plunger 3a, which in FIG. 1 is supported displaceable upwards and downwards in a cylindrical housing 3b. The plunger 3a is impinged with a spring force, so that in the unloaded state the plunger is protracted upwardly.

The contacting units 3 are arranged at a floor element of a first vacuum chamber 4. This vacuum chamber is delimited upwards by the support element 2 and downwards by the already described floor element. Laterally the vacuum chamber is sealed by bellows-like elements. The floor of the first vacuum chamber is furthermore connected via gliding guides 5a and 5b to the housing of the measuring device such that upon compressing the volume of the first vacuum chamber 4 an approaching of the floor of the vacuum chamber to the support element 2 occurs, with the floor always being parallel to the support element.

The measuring device further comprises a suction line 6, which is connected to a suction unit, not shown, to create a vacuum in the first vacuum chamber 4 in a fluid-conducting fashion.

The measuring device further comprises a delay vacuum chamber 7, which is arranged below the first vacuum chamber 4.

In order to perform a measurement a measurement structure 8, here a silicon solar cell that can be contacted at the rear, is placed upon the support element 2. Prior to the placement of the solar cell, ambient pressure is given in the first vacuum chamber 4, and due to the weight of the floor of the first vacuum chamber it is displaced maximally downwards along the gliding guides 5a and 5b. This position is selected such that the contacting units 3 at maximally protracted contact pins penetrate the recesses of the support element 2, however they are not yet contacting the solar cell supported on the support element 2.

The support element 2 includes stopping pins, not shown, so that after the placement of the solar cell via said stopping pins a predetermined positioning of the solar cell occurs on the support element. It is selected such that the contacting points of the solar cell rest above the recesses of the support element 2 and can be electrically contacted accordingly by the contacting units 3 penetrating the recesses.

Upon placement of the solar cell on the support element 2 therefore the recesses of the support element are essentially sealed air-tight in reference to the environment by the solar cell so that in the first vacuum chamber a vacuum can be created in reference to the environment.

Accordingly, a vacuum is created in the first vacuum chamber using the suction unit via the suction line 6. This vacuum leads, on the one hand, to the solar cells being suctioned to the support element 2 via the recesses of the support element 2 due to the vacuum. On the other hand, the volume of the first vacuum chamber 4 is compressed due to the vacuum so that the floor of the first vacuum chamber 4 in FIG. 1 moves upwards and accordingly the contacting units are pressed to the solar cell and an electric contacting occurs.

Upon the contacting units approaching the solar cell by the floor of the first vacuum chamber being raised the contact plungers 3a are pressed into the cylindrical housing 3b, with the above-described spring causing a pressure of the contact plunger upon the solar cell increasing with the further pressing of the contact plunger into the cylindrical housing.

Therefore the measuring device 1 comprises two stops 9a and 9b, which limit the maximum compression of the vacuum chamber 1 and accordingly to the maximum displacement path of the floor of the first vacuum chamber in the direction of the support element 2 and the solar cell resting thereon. This maximum displacement path is selected such that a predetermined compression force of the contacting plunger 3a of the contacting units 3 is yielded.

As described above, the vacuum develops in the first vacuum chamber not instantaneously and accordingly the suction force also develops only gradually, by which the solar cell is suctioned to the support element 2.

The measuring device shown in FIG. 1 comprises therefore a delay vacuum chamber 7, which acts as a delaying element and delays the rising of the floor of the first vacuum chamber.

The delay vacuum chamber 7 is sealed in an air-tight fashion and only connected to the first vacuum chamber 4 via a pressure valve 10, which can be controlled. The pressure valve is embodied such that beginning at a predetermined pressure difference between the first and the second vacuum chamber a gas flow occurs from the delay vacuum chamber into the first vacuum chamber. Prior to reaching the predetermined pressure difference no gas flow occurs, i.e. the two vacuum chambers are sealed from each other in an air-tight fashion. In one measuring process, first via a second suction line 11, which is connected to the delay vacuum chamber 7, a predetermined pressure is created of 0.3 bar to 0.4 bar (i.e. a vacuum of 0.7 to 0.6 bar in reference to the ambient pressure of 1 bar) in the delay vacuum chamber.

Subsequently, as described, the solar cell is placed upon the support element and a vacuum is crated via the suction line 6 in the first vacuum chamber 4. Advantageously a pressure from 0.2 to 0.3 is created in the first vacuum chamber, (i.e. a vacuum from 0.8 to 0.7 in reference to an ambient pressure of 1 bar). If the pressure difference between the first and the second vacuum chamber fails to exceed the predetermined pressure difference of 0.1 bar at the pressure valve 10 no gas flow occurs from the delay vacuum chamber into the first vacuum chamber and the vacuum in the second vacuum chamber counteracts the compression of the first vacuum chamber. The delay vacuum chamber therefore delays the compression of the volume of the first vacuum chamber and thus also the rising of the floor of the first vacuum chamber and the pressure of the contacting units upon the solar cell. The development of the suction force is, however, not delayed.

When the pressure difference exceeds the predetermined value, gas flows from the delay vacuum chamber into the first vacuum chamber. This way it is insured that in case of minor leakage of the delay vacuum chamber which leads to a drop of the vacuum predetermined at the start, the vacuum is increased again in the delay vacuum chamber during the measurement process via the gas flow from the delay vacuum chamber into the first vacuum chamber.

After the measurement has been taken the first vacuum chamber is returned to ambient pressure so that the first vacuum chamber can expand again and accordingly the contacting units 3, 3′ in FIG. 1 move downwards and thus the electric contacting of the solar cell is interrupted. By the vacuum of the delay vacuum chamber 7 the expansion of the first vacuum chamber 4 and thus the lowering of the contacting units is additionally accelerated.

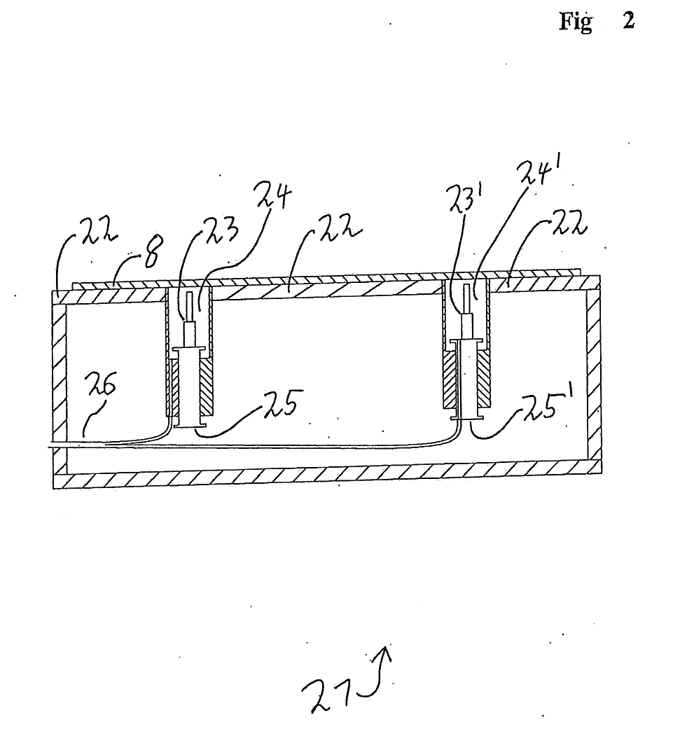

FIG. 2 shows another exemplary embodiment of a measuring device 21 according to the invention having a support element 22, which also comprises recesses embodied as suction openings and which simultaneously can be penetrated by contacting units 23, in order to contact a measurement structure resting on the support element 22.

The contacting units are embodied as spring-loaded contacting pins, as already described in the exemplary embodiment shown in FIG. 1.

FIG. 2 shows, similar to FIG. 1, a schematic cross-section perpendicular in reference to the support element 22.

Contrary to the exemplary embodiment in FIG. 1, in the exemplary embodiment shown in FIG. 2 one vacuum chamber 24 is allocated to each contacting unit.

The vacuum chambers are connected towards the top with the recesses of the support element 22. At the floor of the vacuum chambers a piston (25, 25′) is provided, which can be protracted and retracted, with the contacting unit (23, 23′) being arranged at its top.

The measuring device also comprises a suction line 26, which is connected to a suction unit, not shown. The suction line is connected to each of the vacuum chambers in a fluid conducting fashion. FIG. 2 shows at the left side that the suction line is guided through the floor of the vacuum chamber. Alternatively, it is also possible, as shown in FIG. 2 at the right vacuum chamber, to pass the suction line through the piston.

As already described in FIG. 1, in order to measure, first a measurement structure 8, embodied as a solar cell, is placed upon the support element 22, with here too the support element comprising stops, not shown, for a precise positioning of the solar cell such that the contacting points of the solar cell are located above the recesses of the support element and can be electrically contacted via the contacting units.

Subsequently, using the suction line 26, a vacuum is created in both vacuum chambers so that on the one hand the solar cell is suctioned to the support element and on the other hand, due to the vacuum, the piston is pulled into the vacuum chamber and accordingly a compression of the contacting units occurs to the solar cell. The piston 25, 25′ comprise both at the top as well as the bottom stops so that the maximum displacement path is limited for both protraction as well as retraction. The maximum displacement path during the insertion is selected such that when the piston is maximally pulled into the vacuum chamber a predetermined operating height of the contacting units is yielded, i.e. as described in FIG. 1 the plungers of the contacting units are pressed in by a predetermined path into the corresponding cylindrical housing so that a predetermined compression is reached of the contacting units to the solar cell.

FIG. 2 shows the ratio of the suction force, by which the solar cell is pressed against the support element and the compression of the contacting units and/or the speed by which the contacting units are displaced upwards in FIG. 2 is defined via the ratio of the cross-sectional area (horizontal in FIG. 2) of the vacuum chamber and the cross-sectional area of the piston:

The larger the cross-sectional area of the vacuum chamber in reference to the cross-sectional area of the piston the greater the suction force in reference to the compression force of the contacting units to the solar cell.

Therefore it can be avoided by appropriate sizing that upon being contacted the solar cell lifts off the support element. Thus, in the exemplary embodiment shown in FIG. 2 no additional delay element is required.

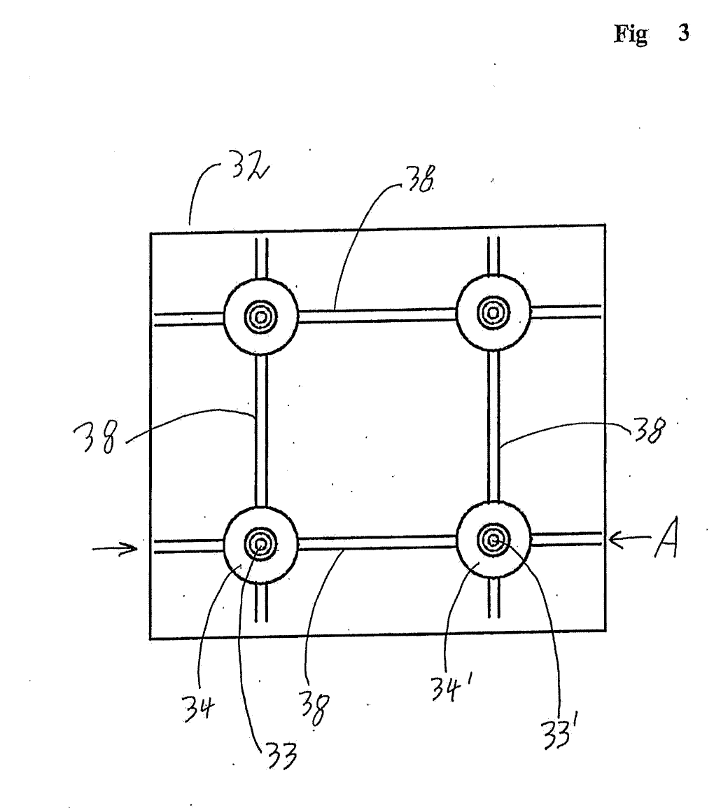

FIG. 3 shows another exemplary embodiment of a measuring device according to the invention in a top view.

Four vacuum chambers are embodied in a support element 32, with the two lower vacuum chambers being marked with the reference characters 34 and 34′ as examples. The vacuum chambers are connected via channels 38 in a fluid-conducting fashion. These channels are embodied in the support element open to the top, so that placing a measurement structure onto the support element 32 leads to a sealing of the channels in the direction of the measurement structure and a fluid-conducting connection develops between the vacuum chambers. This way, the measurement structure is not only pressed to the support element 32 by the vacuum chambers but additionally via the channels 38.

The measuring device according to FIG. 3 comprises four contacting units, each of which is arranged in a vacuum chamber.

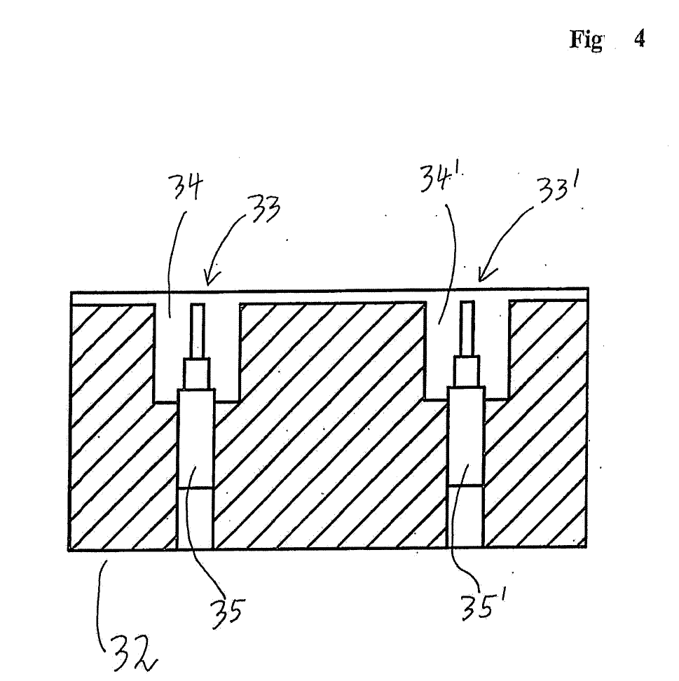

FIG. 4 shows a cross-section along a line A in FIG. 3, perpendicular in reference to the plane of the drawing in FIG. 3, with the illustration 4 not being to scale; the thickness of the support element 32 in reference to the distance of the vacuum chamber 34 and 34′ is strongly enlarged for better visibility.

The channel 38 connects the vacuum chambers 34 and 34′ in a fluid-conducting fashion and extends via the vacuum chambers to the proximity of the edge of the support element 32 in order to additionally increase the area at which the measurement structure is suctioned.

One contacting unit (33, 33′) each is arranged in the vacuum chambers 34, 34′.

The contacting units each comprise fastening elements embodied as mobile pistons 35, 35′, which are supported in an articulate fashion in the support element 32 such that they are displaceable upwards and downwards in FIG. 4 and thus can be protracted into and retracted from the vacuum chambers. The pistons 35 and 35′ are here supported in a movable fashion in the support element 32 such that the vacuum chambers 34 and 34′ are fluid-tight towards the bottom, as shown in FIG. 4.

Now, if a measurement structure is placed upon the support element 32, the vacuum chambers 34 and 34′ as well as the channels 38 are sealed in a fluid-tight fashion by the measurement structure. Subsequently, in one, preferably in several vacuum chambers a vacuum is created using a suction line (not shown). An equally strong vacuum develops based on the fluid-conducting connection of the vacuum chambers via the channels 38 in all vacuum chambers and accordingly the measurement structure is suctioned with the same force over the entire suction area towards the support element 32.

Based on the vacuum in the vacuum chambers 34 and 34′ the pistons 35 and 35′ of the contacting units 33 and 33′ move upwards in FIG. 4, i.e. into the vacuum chambers so that the spring-loaded contact pins of the contacting units are pressed to the measuring side of the measurement structure and an electric contact forms thereto.

The pistons 35, 35′ comprise stops (not shown), which delimit the maximal positions during protracting and retracting.

The contacting units are shown in FIGS. 1 through 4 not in a cross-section, i.e. particularly the springs for impinging the contacting pins of the contacting units are not shown in FIG. 4.

In the exemplary embodiments the contacting units each have electric contacting cables, not shown, which lead to respective connection sockets at the measuring device so that via the connection socket an electric contact is possible to the measurement apparatuses, such as current/voltage measurement devices.

1. A measuring device (1, 21) for electric measurement of a measurement structure (8) which can be contacted at one measuring side, comprising at least two contacting units (3, 3′, 23, 23′, 33, 33′) adapted for an electrical contacting of the measurement structure (8) and at least one support element (2, 22, 32) adapted to receive the measurement structure (8) with a measuring side on the support element (2, 22, 32), with the support element (2, 22, 32) and the contacting units (3, 3′, 23, 23′, 33, 33′) being arranged such that the measurement structure (8) resting on the support element (2, 22, 32) can be contacted in an electrically conducting fashion via the contacting units at the measuring side, the two contacting units are electrically isolated from each other, at least one suction line (6, 26) adapted to be connected to a suction unit and at least one suction opening arranged at least one of in or on the support element (2, 22, 32) is connected in a fluid-conducting fashion to the suction line (6, 26), such that the measurement structure (8) is adapted to be pressed via suction from the suction opening to the support element (2, 22, 32), the contacting units (3, 3′, 23, 23′, 33, 33′) are arranged articulate in reference to the support element (2, 22, 32), and an actuator unit, which is effectively connected to the contacting units (3, 3′, 23, 23′, 33, 33′) such that when the measurement structure (8) rests on the support element (2, 22, 32) the contacting units are pressed via the actuator unit toward the measurement structure (8) resting on the support element (2, 22, 32) for an electrical contacting and when the contacting units (3, 3′, 23, 23′, 33, 33′) are pressed against the measurement structure (8), said measurement structure (8) is adapted to be exclusively pressed to the support element (2, 22, 32) by way of suction and a weight of the measurement structure (8).

2. A measuring device (1, 21) according to claim 1, wherein the suction opening and the actuator unit are embodied such that during the suctioning of the measurement structure (8) to the support element (2, 22, 32) and compression of the contacting pins to the measurement structure (8) for an electrical contacting, a total of suction forces by which the measurement structure (8) is pressed to the support element (2, 22, 32) is always greater than a total of contacting forces, by which the contacting units (3, 3′, 23, 23′, 33, 33′) are pressed against the measuring side of the measurement structure (8).

3. A measuring device (1, 21) according to claim 1, wherein the actuating unit is embodied such that the contacting units (3, 3′, 23, 23′, 33, 33′) can be displaced via the actuator unit into a rest position, in which no contacting occurs of the measurement structure (8) resting on the support element (2, 22, 32), and a contacting position, in which the measurement structure (8) resting on the support element (2, 22, 32) is adapted to be electrically contacted by the contacting units.

4. A measuring device (1, 21) according to claim 1, wherein there are at least two of the suction openings, and for each of the contacting units (3, 3′, 23, 23′, 33, 33′) one of the suction openings is arranged in an area of the contacting unit.

5. A measuring device (1, 21) according to claim 1, wherein the support element (2, 22, 32) comprises at least one recess and the contacting units (3, 3′, 23, 23′, 33, 33′), adapted for electrically contacting the measurement structure (8), are each guided by at least one of the recesses of the support element and at least one of the recesses is embodied as a suction opening, through which upon contact by the measurement structure (8) at least one of the contacting units is guided.

6. A measuring device (1, 21) according to claim 1, wherein the actuator unit comprises at least one vacuum chamber (4, 24, 24′, 34), which on one side is connected in a fluid-conducting fashion to the suction line (6, 26) and on an other side is connected to at least one suction opening, and the vacuum chamber (4, 24, 24′, 34) has a volume that can be compressed by creating a vacuum in the vacuum chamber (4, 24, 24′, 34) and at least one of the contacting units is arranged in the vacuum chamber (4, 24, 24′, 34) such that a compression of the vacuum chamber (4, 24, 24′, 34) is adapted to cause a pressing of the contacting unit against the measuring side of the measurement structure (8) resting on the support element (2, 22, 32).

7. A measuring device (1, 21) according to claim 6, wherein the actuator unit comprises at least two of the vacuum chambers (24, 24′, 34), with each of the vacuum chambers (24, 24′, 34) each comprising at least one articulate fastening element for the contacting unit comprising at least one movable piston (25, 25′, 35, 35′), the vacuum chamber (24, 24′, 34) is supported such that it can protract and retract, with at least one contacting unit (23, 23′) being arranged on the fastening element (25, 25′, 35, 35′) such that upon the fastening element being inserted into the vacuum chamber (24, 24′, 34) the contacting unit is pressed against the measuring side of the measurement structure resting on the support element (22).

8. A measuring device (1, 21) according to claim 7, wherein the actuator unit comprises at least one delay element, which cooperates with the contacting units (3, 3′, 3″, 23, 23′, 33, 33′) such that during a displacement of the contacting units via the actuator unit a displacement speed of the contacting units is reduced by the delay element.

9. A measuring device (1, 21) according to claim 8, wherein the delay element comprises a delay vacuum chamber (7, 34′), which is arranged cooperating with the first vacuum chamber (4) such that a compression of a first one of the vacuum chambers (4) is delayed by a vacuum in a second one of the vacuum chambers (7).

10. A measuring device (1, 21) according to claim 8, wherein there are a plurality of the support elements (2, 22, 23) embodied interchangeably for different contacting points of a measurement structure (8), with each of the support elements (2, 22, 32) comprising recesses according to each predetermined contacting point.

11. A measuring device (1, 21) according to claim 8, wherein there are a plurality of the support elements (2, 22, 32) embodied interchangeably having suction openings for different suction forces, with the support elements being different with regards to a total size of the suction openings.

12. A method for contacting a measurement structure (8), which can be electrically contacted at one measuring side, comprising the following processing steps:
A placing of the measurement structure (8) with a measuring side onto a support element (2, 22, 32), and
B electrically contacting the measurement structure (8) by at least two contacting units (3, 3′, 3″, 23, 23′, 33, 33′), electrically isolated from each other, being pressed against the measuring side of the measurement structure (8), and suctioning the measurement structure (8) in step B via a vacuum for contacting the support element (2, 22, 32) via suction openings at least one of at or in the support element (2, 22, 32) and upon contacting the measurement structure (8) said structure is exclusively pressed to the support element (2, 22, 32) via suction and a weight of the measurement structure (8).

13. A method according to claim 12, wherein during pressing of the contacting units (3, 3′, 3″, 23, 23′, 33, 33′) at the measuring side of the measurement structure (8) and during a measuring process using contacting units pressed to the measurement structure (8) a suction force, by which the measurement structure (8) is pressed to the support element (2, 22, 32) is always greater than a total of contacting forces by which the contacting units are pressed to the measuring side of the measurement structure (8).

14. A method according to claim 12, wherein in step B a delayed approach of the contacting units (3, 3′, 3″, 23, 23′, 33, 33′) occurs to the measuring side of the measurement structure (8).

15. A method according to claim 12, wherein at least one contacting unit is arranged in or at a vacuum chamber (4, 24, 24′, 34) having a volume that is compressible by the creation of a vacuum, and compression of the contacting unit to the measurement structure occurs by a vacuum created in the vacuum chamber.
